(19) United States
(12) Patent Application Publication
(10) Pub. No.: US 2026/0342048 A1
(43) Pub. Date: Oct. 29, 2026

(54) ULTRA FAST LASERS VIA METAOPTICS

(71) Applicant: ams-OSRAM Asia Pacific Pte. Ltd., Singapore (SG)

(72) Inventor: Nemanja NIKETIC, Mont-sur-Rolle (CH)

(21) Appl. No.: 19/486,046

(22) PCT Filed: Jul. 29, 2024
(86) PCT No.: PCT/EP2024/071437

§ 371 Date: Nov. 20, 2025

(30) Foreign Application Priority Data
Sep. 1, 2023 (DE) 10 2023 123 602.4

(51) Int. Cl. H01S 5/183

(52) U.S. Cl. CPC H01S 5/18361

(57) ABSTRACT

A pulsed laser source is provided. The pulsed laser source may include an emitting structure configured to generate a continuous wave of a coherent electromagnetic radiation of a frequency. The pulsed laser source may further include at least one mirror structure. The mirror structure may include a plurality of optical nano-elements. The plurality of optical nano-elements may be configured to include a resonance frequency corresponding to the frequency of the coherent electromagnetic radiation such that the continuous wave of coherent electromagnetic radiation is substantially reflected from the mirror structure.

This disclosure generally relates to components for generating ultra-short laser pulses.

Ultra-fast laser pulses can be designed with active elements or passive elements. In known ultra-fast lasers, a mirror is arranged in the optical cavity of the laser, and thus making constraints in making a continuous wave laser into a pulsed laser. Exemplary active elements are acousto-optic modulators or electro-optic modulators, and are high in complexity and pulse lengths are in an order of picoseconds. Exemplary passive elements are for example saturable absorbers, and pulse lengths are in an order of femtoseconds.

It is an objective of the invention to provide a pulsed laser source having an improved integrability.

In one aspect, a pulsed laser source is provided including an emitting structure configured to generate a continuous wave of a coherent electromagnetic radiation of a frequency. The pulsed laser source further includes at least one mirror structure. The mirror structure includes a plurality of optical nano-elements. The plurality of optical nano-elements may be configured to include a resonance frequency corresponding to the frequency of the coherent electromagnetic radiation such that the continuous wave of coherent electromagnetic radiation is substantially reflected from the mirror structure.

The optical component utilizes the resonant properties of the optical nano-elements. This way, the optical component can be a passive optical element which may yield femtosecond laser pulses. In other words, the array of resonant optical nano-elements of the mirror structure may effectively be a time dependent mirror. The mirror structure may behave like an optical mirror for continuous waves (CW). The optical component may be transmissive for short pulses. Thus, a laser utilizing the mirror structure may transmit short pulses of laser light while reflecting a continuous wave of laser light. Thus, laser utilizing the mirror structure as mirror may provide short pulses of laser light in a passive manner. The characteristics of the mirror structure can theoretically be explained using the Ewald-Oseen extinction theorem in a transient domain.

Thus, the mirror structure may be used as a time-dependent mirror for a coherent laser source to emit laser pulses. The mirror structure can introduce simplicity in designing ultra-fast lasers. A vertical cavity surface emitting laser, VCSEL, component may include an optical cavity, e.g. formed by layers of the coherent electromagnetic radiation generating structure, the dielectric layer(s), distributed Bragg reflector(s), DBR, and the (optional) embedding layer(s). The mirror structure can be arranged outside of the optical cavity, e.g. external to the optical cavity. This may simplify the design process of the VCSEL component. In other words, the mirror structure does not need to be arranged in the laser cavity as it is done in comparative laser components but outside the optical cavity, e.g. as a mirror of the laser. In this way, there is no principal constraint in making any continuous wave laser into a pulsed laser.

In another aspect, a method to manufacture a pulsed laser source is provided. The method including: forming an emitting structure configured to generate a continuous wave of a coherent electromagnetic radiation of a frequency; and forming at least one mirror structure including a plurality of optical nano-elements, wherein the plurality of optical nano-elements is configured to include a resonance frequency corresponding to the frequency of the coherent electromagnetic radiation such that the continuous wave of coherent electromagnetic radiation is substantially reflected from the mirror structure.

This way, a pulsed laser source having an improved vertical integrability can be provided.

In the drawings, like reference characters generally refer to the same parts throughout the different views. The drawings are placed upon illustrating the principles of the invention. In the following description, various aspects of the invention are described with reference to the following drawings, in which:

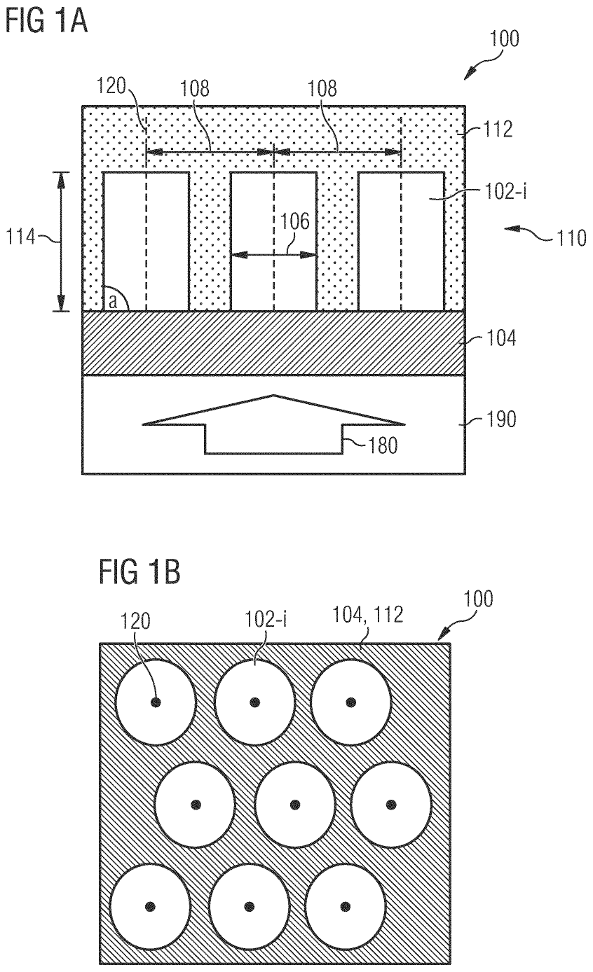

FIG. 1A to FIG. 1B show diagrams illustrating characteristics of an optical metasurface;

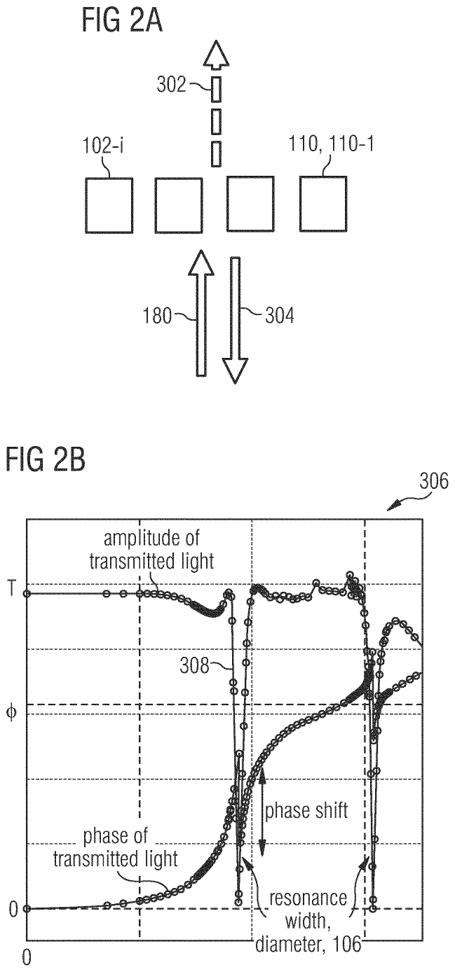

FIG. 2A to FIG. 2B show diagrams illustrating characteristics of a metasurface according to an aspect of the invention;

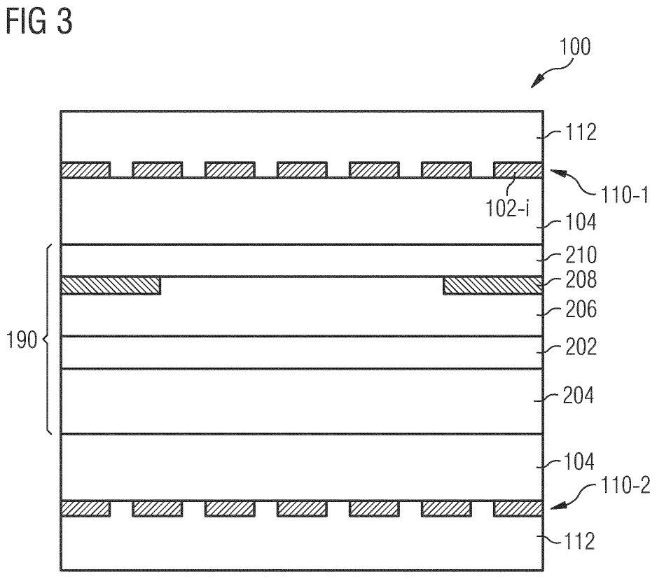

FIG. 3 shows a schematic cross-sectional view of a pulsed laser source according to an aspect of the invention;

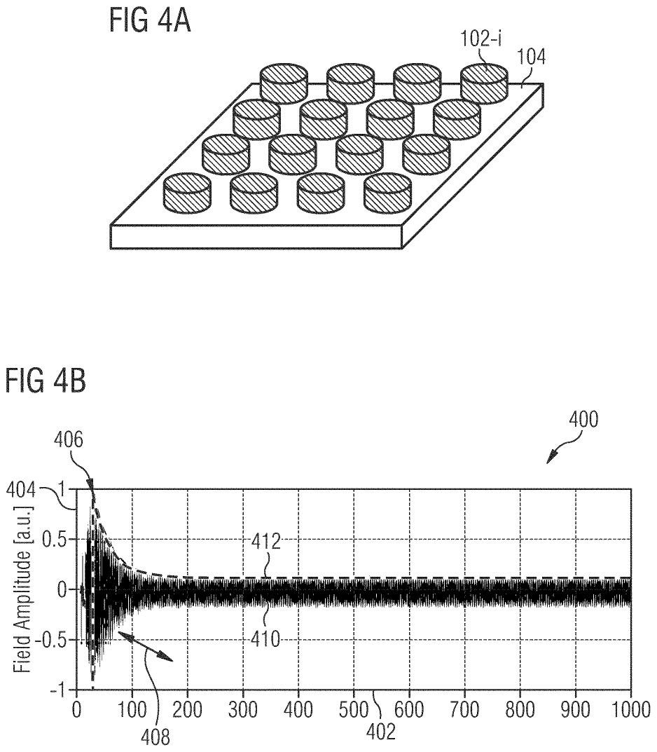

FIG. 4A to FIG. 4B illustrate diagrams of an optical metasurface according to another aspect of the invention;

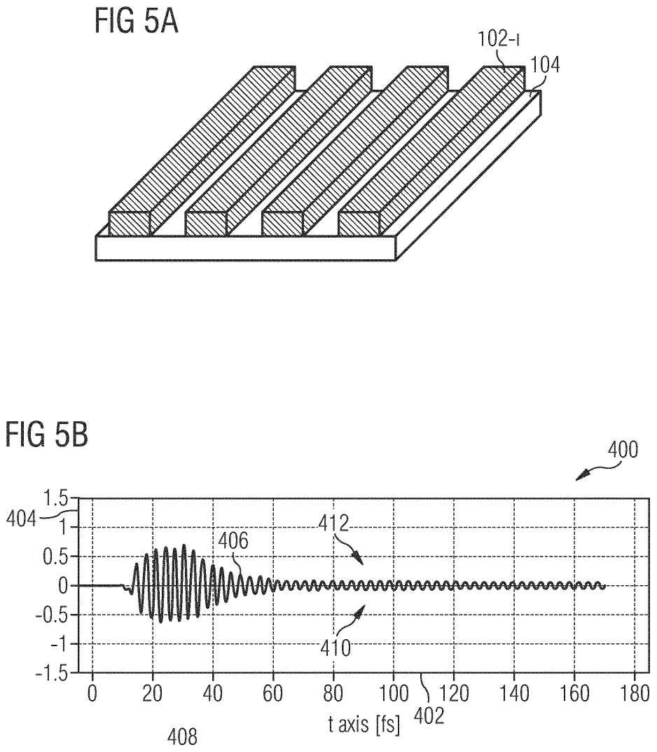

FIG. 5A to FIG. 5B illustrate diagrams of an optical metasurface according to another aspect of the invention; and

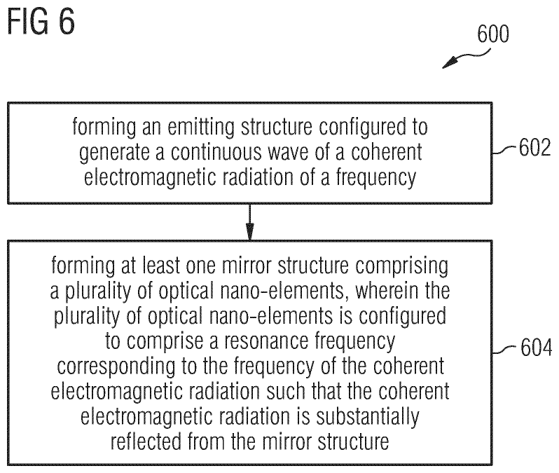

FIG. 6 flow diagram of a method to manufacture an optical metalens component.

The following detailed description refers to the accompanying drawings that show, by way of illustration, specific details and aspects in which the disclosure may be practiced. One or more aspects are described in sufficient detail to enable those skilled in the art to practice the disclosure. Other aspects may be utilized and structural, logical, and electrical changes may be made without departing from the scope of the disclosure. The various aspects described herein are not necessarily mutually exclusive, as some aspects can be combined with one or more other aspects to form new aspects. Various aspects are described in connection with methods and various aspects are described in connection with devices. However, it may be understood that aspects described in connection with methods the drawings, it should be noted that like reference numbers are used to depict the same or similar elements, features, and structures. Throughout the drawings, it should be noted that proportions are not necessary to scale and that the size of features may be emphasized for ease of illustration.

Illustratively, a vertical cavity surface emitting laser, VCSEL, component having at least one metasurface mirror (a mirror structure including a plurality of optical nano-elements) is provided that emits a pulsed laser beam (also denoted as laser pulses). The wavelength of operation of the pulsed laser source can flexibly be tuned by scaling the dimension of the individual optical nano-elements forming the metasurface of the mirror structure. One of the features of the VCSEL component is that it is able to emit light in both directions (up and down). However, it is possible to have an emission also in one direction by using non-identical mirror structures with slightly detuned resonant frequencies and thus making one of the mirrors more transparent (less reflective) to ensure one side emission.

FIG. 1A shows a schematic cross-sectional side view of a VCSEL component. FIG. 1B shows a schematic cross-sectional top view of a VCSEL component. The vertical cavity surface emitting laser, VCSEL, component 100 may include a coherent electromagnetic radiation generating structure 190 configured to generate a continuous wave of a coherent electromagnetic radiation 180 of a frequency. A dielectric layer 104 may be formed on or above the coherent electromagnetic radiation generating structure 190. At least one mirror structure 110 may be arranged on or above the dielectric layer 104, or on or above the radiation generating structure 190 in case the dielectric layer 104 is optional. For example, the coherent electromagnetic radiation generating structure 190, the mirror structure 110, and the dielectric layer 104 may be integrated on a shared semiconductor substrate (not illustrated).

Note, the dielectric layer 104 is transparent or about transparent (transmission larger than 0.95) for the light 180 generated by the coherent electromagnetic radiation generating structure 190. The plurality of optical nano-elements 102-i may be formed directly on a surface of the dielectric layer 104.

The mirror structure 110 includes a plurality of optical nano-elements 102-i (with i being an integer). An arrangement of optically coupled optical nano-elements 102-i, e.g. pillars, has a resonance frequency (or resonance wavelength) in the pillar library depending among others on the size 106 (e.g. diameter) and pitch 108 of the pillars forming the arrangement. Optically coupled may be understood that the optical nano-elements 102-i may cause an optical resonance in the optical spectrum. Thus, the arrangement of optically coupled optical nano-elements 102-i may reflect the continuous wave 304 of the coherent electromagnetic radiation corresponding in its frequency to the resonance frequency of the arrangement of optically coupled optical nano-elements 102-i, as illustrated in FIG. 2A. Laser pulses 302 corresponding to the flank of the resonance of the continuous wave may be transmitted by mirror structure, as illustrated in FIG. 2A and in described in more detail in FIG. 4B and FIG. 5B.

Note, the resonance may not be caused by the geometry of a single optical nano-element, but it is a collective phenomenon of optically coupled optical nano-elements 102-i in the arrangement of optically coupled optical nano-elements 102-i.

In other words, the pulsed laser source 100 may include an emitting structure 190 configured to generate a continuous wave of a coherent electromagnetic radiation of a frequency. The pulsed laser source 100 may further include at least one mirror structure 110. The mirror structure 110 may include a plurality of optical nano-elements 102-i. The plurality of optical nano-elements 102-i may be configured to include a resonance frequency (see FIG. 2B) corresponding to the frequency of the coherent electromagnetic radiation such that the continuous wave of coherent electromagnetic radiation is substantially reflected from the mirror structure 110.

In other words, the pulsed laser source 100 may be configured that none or substantially none of the coherent electromagnetic radiation of the continuous wave is emitted to an environment of the pulsed laser source.

As illustrated in the schematic top view in FIG. 1B, the optical nano-elements of at least a subset of the plurality of optical nano-elements are arranged in arrangement positions 120. The resonance frequency may correspond to the pitch 108 between the optical nano-elements 102-i in the arrangement positions. For example, the optical nano-elements of at least a subset of the plurality of optical nano-elements are arranged in a regular grid of positions.

Alternatively (not illustrated), or for a subset of the plurality of optical nano-elements, the optical nano-elements of at least a subset of the plurality of optical nano-elements are arranged in arrangement position corresponding to arrangement positions offset from a regular grid of positions, wherein each arrangement position corresponds to a grid position and an offset vector regarding the grid position. The offset vectors are configured such that the lengths of the offset vectors correspond to a predetermined distribution function. This way, the line width of the resonance, and hence a pulse length of the laser pulses may be set as desired.

In other words, any one of a structure of the optical nano-elements 102-i and an arrangement of the arrangement positions of the optical nano-elements 102-i may be configured such that the plurality of optical nano-elements 102-i may include an optical resonance frequency corresponding to the frequency of the light 180 generated by the coherent electromagnetic radiation generating structure 190. The optical resonance frequency of the plurality of optical nano-elements 102-i corresponds to any one of a lateral extension 106 optical nano-elements 102-i, a tapering angle “a” of the optical nano-elements 102-i, a lateral distance 108 of adjacent optical nano-elements 102-i (e. g. center-to-center, or sidewall-to-sidewall; also denoted as pitch), a height 114 optical nano-elements 102-i, a shape of the optical nano-elements 102-i (e.g. any one of a circular cross sectional shape, an shape), a material (e.g. refractive index) of the plurality of optical nano-elements 102-i, an arrangement of the plurality of optical nano-elements 102-i, an incident angle of the light 180 on the plurality of optical nano-elements 102-i, or any combination thereof. The optical nano-elements 102-i may be spaced apart by a distance 108 in a range from about 100 nm to about 1000 nm, e.g. in a range from about 200 nm to about 600 nm, e.g. in a from about 250 nm to about 500 nm. The optical nano-elements 102-i may have a height 114 in a range from about 10 nm to about 10000 nm, e.g. in a range from about 200 nm to about 1600 nm, e.g. in a range from about 450 nm to about 800 nm. The optical nano-elements 102-i may have a lateral extension 106 in a range from about 10 nm to about 1000 nm, e.g. in a range from about 50 nm to about 700 nm, e.g. in a range from about 100 nm to about 350 nm. The optical nano-elements 102-i may have a tapering angle “a” in a range from about 80° to about 90°, e. g. in a from about 82° to about 90°, e. g. in a from about 85° to about 88°.

The plurality of the optical nano-elements 102-i may be arranged in a regular pattern. The arrangement of the arrangement positions of the optical nano-elements may correspond to a regular grid of positions, wherein each arrangement position corresponds to a grid position. The regular grid may be any one of a monoclinic grid, an orthorhombic grid, a tetragonal grid and a hexagonal grid.

The mirror structure 110 having the plurality of optical nano-elements 102-i can have a high reflectivity and low transmission for a continuous wave of electromagnetic radiation having a frequency corresponding to the optical resonance frequency of the plurality of optical nano-elements 102-i.

The pulsed laser source 100 may further include an encapsulation layer 112 on or above the plurality of optical nano-elements 102-i. The encapsulation layer 112 may be further formed in the interspace between adjacent optical nano-elements 102-i. The encapsulation layer 112 can protect the plurality of optical nano-elements 102-i from physical damage and as dust interaction protection. Alternatively, or in addition, the encapsulation layer 112 can provide a surface having a lower roughness (e.g. root mean square roughness (RMS)) than the surface of the dielectric layer 104 having the plurality of optical nano-elements 102-i. However, the encapsulation layer 112 can be optional depending on the application of the pulsed laser source 100. The encapsulation layer 112 may be any kind or organic or inorganic material having a refractive index of about 1.50 for the electromagnetic radiation received from an eradiation generating structure 190. Thus, a surface of the mirror structure 110 may include or correspond to an emission surface of the pulsed laser source 100 to emit pulsed electromagnetic radiation generated by the mirror structure 110 based on resonance of the coherent electromagnetic radiation to an environment of the pulsed laser source 100. The encapsulation layer 112 may at least partially fill over overfill the space between the optical nano-elements

The pulsed laser source 100, e.g. the mirror structure 110, may include a substrate that may be any one of amorphous silica, glass, etc., e. g. a plastic, e.g. a polycarbonate substrate or an epoxide substrate. The substrate may have a planar shaped, e.g. may be a wafer. Alternatively, the substrate may have a bowed shaped, e.g. glass of AR- or VR-glasses.

FIG. 2A to FIG. 2B show diagrams illustrating characteristics of a metasurface according to an aspect of the invention. FIG. 2A illustrates a perspective view of the optical nano-elements 102-i of a mirror structure 110, 110-1 of the pulsed laser source and the electromagnetic radiation 180 generated by the coherent electromagnetic radiation generating structure. Note, pulsed light 304 may be transmitted through the mirror structure 110, 110-1 while the continuous wave 302 is reflected by the mirror structure 110, 110-1, which can be explained using the Ewald-Oseen extinction theorem in a transient domain.

FIG. 2B shows a diagram 306 illustrating the transmission T and phase shift φ of light transmitted by the mirror structure 110, 110-1.

Note that the term light and coherent electromagnetic radiation may refer to any kind of coherent electromagnetic radiation in the spectrum of visible and invisible electromagnetic radiation, including ultraviolet (UV) radiation, near infrared (IR) radiation, middle infrared radiation, and microwaves. For example, the electromagnetic pulses emitted by the laser source may be generated in microwave waveguides at frequencies/wavelengths which are not used for guiding

As illustrated in FIG. 2B, the amplitude of the transmitted continuous wave drops to zero at the resonance 308 corresponding to a phase shift of the transmitted radiation. However, the transmission does not drop in a steep step-like manner to zero, as illustrated in FIG. 4B and FIG. 5B but with a time constant 406. The time constant 406 corresponds to the pulse width of laser pulses transmitted by the mirror structure.

FIG. 3 shows a schematic cross-sectional view of a pulsed laser source 100 according to an aspect of the invention. The coherent electromagnetic radiation generating structure 190 may include a p-contact semiconductor layer 206, an n-contact semiconductor layer 204 and an active region 202 arranged between the p-contact semiconductor layer 206 and the n-contact semiconductor layer 204. A transparent contact layer 210, e.g. formed from a transparent conductive oxide (TCO), may be formed on the p-contact semiconductor layer 206. An electrical current aperture structure 208 may be formed between the p-contact semiconductor layer 206 and the transparent contact layer 210.

For example, optical nano-elements 102-i may be formed of TiO₂ having a refractive index of about 2.6, the dielectric layer 104 may be formed of SiO₂ having a refractive index of about 1.45. The contact layer 210 may be formed of Indiumtinoxide (ITO) and the electrical current aperture structure 208 may be formed of a dielectric material, e.g. an oxide. The p-contact semiconductor layer 206 may be formed of p-GaN and the n-contact semiconductor layer 204 may be formed of n-GaN having a refractive index of about 2.5 respectively.

The coherent electromagnetic radiation generating structure 190 may have a first side and a second side opposite to the first side. The mirror structure 110 described above may be a first mirror structure 110-1 arranged at the first side of the coherent electromagnetic radiation generating structure 190. The pulsed laser source 100 may further include a second mirror structure 110-2 arranged at the second side of the coherent electromagnetic radiation generating structure 190. The second mirror structure 110-2 may be configured corresponding to the first mirror structure 110-1. Alternatively, the plurality of optical nano-elements 102-i of the first mirror structure 110-1 may differ in at least one characteristic from the plurality of optical nano-elements 102-i of the second mirror structure 110-2. The characteristic may be any one of a distance between adjacent nano-optical elements, a lateral extension of the nano-optical elements, a shape of nano-optical elements, and a tapering angle of the nano-optical elements of the subset. Alternatively, the second mirror structure 110-2 may include a distributed Bragg reflector (DBR). Alternatively, or in addition, the second mirror structure 110-2 may include a plurality of optical nano-elements, wherein the plurality of optical nano-elements may be configured to include a resonance frequency corresponding to the frequency of the coherent electromagnetic radiation such that the continuous wave of coherent electromagnetic radiation is substantially reflected from the mirror structure. For example, the second mirror structure 110-2 may be configured to increase the purity of the reflected light (corresponding to 302 in FIG. 2A), and the first mirror structure 110-1 may emit the laser pulses.

FIG. 4A to FIG. 4B illustrate diagrams of an optical metasurface according to another aspect of the invention. FIG. 4A illustrated a perspective view of optical nano-elements formed in a shape of pillars. At least a subset of the plurality of optical nano-elements may include nano-elements in a pillar shape. FIG. 4B illustrates a field evolution 400 showing the field amplitude 404 as a function of time 402 at the resonance condition 308 for pillar shaped optical nano-elements as illustrated in FIG. 4A having a pillar diameter of 187 nm. regime 412 corresponding to a fully compensated incident wave 410. Thus, in the transient regime 406, a wave is transmitted, e.g. an uncompensated incident wave (also denoted as laser pulses) 408 is transmitted having a time constant of 30 fs.

FIG. 5A to FIG. 5B illustrate diagrams of an optical metasurface according to another aspect of the invention. FIG. 5A illustrated a perspective view of optical nano-elements formed in a line shape. At least a subset of the plurality of optical nano-elements may include nano-elements in a line shape. FIG. 5B illustrates the field evolution 400 showing the filed amplitude as a function of time at the resonance condition 308 for line shaped optical nano-elements as illustrated in FIG. 5A having a line width of 236 nm, a height of 500 nm, a pitch of 500 nm, a wall angle of 90° using a wavelength of 940 nm. Illustrated is a transient regime 406 towards a steady state regime 412 corresponding to a fully compensated incident wave 410. Thus, in the transient regime 406, a wave is transmitted, e.g. an uncompensated incident wave (also denoted as laser pulses) 408 is transmitted having a time constant of 20 fs.

FIG. 6 shows a flow diagram of a method to manufacture an optical metalens component. The method 600 may include: forming 602 an emitting structure configured to generate a continuous wave of a coherent electromagnetic radiation of a frequency; and forming 604 at least one mirror structure may include a plurality of optical nano-elements, wherein the plurality of optical nano-elements may be configured to include a resonance frequency corresponding to the frequency of the coherent electromagnetic radiation such that the continuous wave of coherent electromagnetic radiation is substantially reflected from the mirror structure.

The coherent electromagnetic radiation may include a coherence length, and wherein the mirror structure is arranged within the coherence length. The pulsed laser source may be configured that none or substantially none of the coherent electromagnetic radiation of the continuous wave is emitted to an environment of the pulsed laser source 100.

The mirror structure is a first mirror structure and the pulsed laser source further may include a second mirror structure, wherein the second mirror structure is formed as a distributed Bragg reflector. Alternatively, the second mirror structure may include a plurality of optical nano-elements, wherein the plurality of optical nano-elements may be configured to include a resonance frequency corresponding to the frequency of the coherent electromagnetic radiation such that the continuous wave of coherent electromagnetic radiation is substantially reflected from the mirror structure.

The method may further include any feature as described for the device above.

In the following some examples are described, which relate to what is described herein and shown in the figures.

Example 1 is a pulsed laser source, including: an emitting structure configured to generate a continuous wave of a coherent electromagnetic radiation of a frequency; and at least one mirror structure including a plurality of optical nano-elements, wherein the plurality of optical nano-elements is configured to include a resonance frequency corresponding to the frequency of the coherent electromagnetic radiation such that the continuous wave of coherent electromagnetic radiation is substantially reflected from the mirror structure.

In Example 2 the subject matter of Example 1 can optionally include that the pulsed laser source includes an optical cavity, wherein the plurality of optical nano-elements is arranged outside of the optical cavity.

In Example 3 the subject matter of Example 1 or 2 can optionally include that the at least a subset of the plurality of optical nano-elements includes nano-elements in a pillar shape.

In Example 4 the subject matter of any one of Examples 1 to 3 can optionally include that the at least a subset of the plurality of optical nano-elements includes nano-elements in a line shape.

In Example 5 the subject matter of any one of Examples 1 to 4 can optionally include that the optical nano-elements of at least a subset of the plurality of optical nano-elements are arranged in arrangement positions, wherein the resonance frequency corresponds to the pitch between the optical nano-elements in the arrangement positions.

In Example 6 the subject matter of any one of Examples 1 to 5 can optionally include that the optical nano-elements of at least a subset of the plurality of optical nano-elements are arranged in a regular grid of positions.

In Example 7 the subject matter of any one of Examples 1 to 6 can optionally include that the optical nano-elements of at least a subset of the plurality of optical nano-elements are arranged in arrangement position corresponding to arrangement positions offset from a regular grid of positions, wherein each arrangement position corresponds to a grid position and an offset vector regarding the grid position.

In Example 8 the subject matter of Example 7 can optionally include that the offset vectors are configured such that the lengths of the offset vectors correspond to a predetermined distribution function.

In Example 9 the subject matter of any one of Examples 1 to 8 can optionally include that the coherent electromagnetic radiation includes a coherence length, and wherein the mirror structure is arranged within the coherence length.

In Example 10 the subject matter of any one of Examples 1 to 9 can optionally include that the pulsed laser source is configured that substantially none of the coherent electromagnetic radiation of the continuous wave is emitted to an environment of the pulsed laser source.

In Example 11 the subject matter of any one of Examples 1 to 10 can optionally include that the mirror structure is a first mirror structure and the pulsed laser source further includes a second mirror structure, wherein the second mirror structure includes a distributed Bragg reflector.

In Example 12 the subject matter of any one of Examples 1 to 10 can optionally include that the mirror structure is a first mirror structure and the pulsed laser source further includes a second mirror structure, wherein the second mirror structure includes plurality of optical nano-elements, wherein the plurality of optical nano-elements is configured to include a resonance frequency corresponding to the frequency of the coherent electromagnetic radiation such that the continuous wave of coherent electromagnetic radiation is substantially reflected from the mirror structure.

Example 13 is a method for manufacturing a pulsed laser source, the method including: forming an emitting structure configured to generate a continuous wave of a coherent electromagnetic radiation of a frequency; and forming at least one mirror structure including a plurality of optical nano-elements, wherein the plurality of optical nano-elements is configured to include a resonance frequency corresponding to the frequency of the coherent electromagnetic radiation such that the continuous wave of coherent electromagnetic radiation is substantially reflected from the mirror structure.

In Example 14 the subject matter of Example 13 can optionally include that the coherent electromagnetic radiation includes a coherence length, and wherein the mirror structure is arranged within the coherence length.

In Example 15 the subject matter of any one of Examples 13 to 14 can optionally include that the pulsed laser source is configured that substantially none of the coherent electromagnetic radiation of the continuous wave is emitted to an environment of the pulsed laser source.

In Example 16 the subject matter of any one of Examples 13 to 15 can optionally include that the mirror structure is a first mirror structure and the pulsed laser source further includes a second mirror structure, wherein the second mirror structure is formed as a distributed Bragg reflector.

In Example 17 the subject matter of any one of Examples 13 to 15 can optionally include that the mirror structure is a first mirror structure and the pulsed laser source further includes a second mirror structure, wherein the second mirror structure is formed including a plurality of optical nano-elements, wherein the plurality of optical nano-elements is configured to include a resonance frequency corresponding to the frequency of the coherent electromagnetic radiation such that the continuous wave of coherent electromagnetic radiation is substantially reflected from the mirror structure.

The method may further include any feature as described for the device above.

The word “exemplary” is used herein to mean “serving as an example, instance, or illustration.” Any example or design described herein as “exemplary” is not necessarily to be construed as preferred or advantageous over other examples or designs.

The words “plurality” and “multiple” in the description or the claims expressly refer to a quantity greater than one. The terms “group (of)”, “set [of]”, “collection (of) ”, “series (of) ”, “sequence (of)”, “grouping (of)”, etc., and the like in the description or in the claims refer to a quantity equal to or greater than one, i.e. one or more. Any term expressed in plural form that does not expressly state “plurality” or “multiple” likewise refers to a quantity equal to or greater than one.

The term “connected” can be understood in the sense of a (e.g. mechanical, optical and/or electrical), e.g. direct or indirect, connection and/or interaction. For example, several elements can be connected together mechanically such that they are physically retained (e.g., a plug connected to a socket) and electrically such that they have an electrically conductive path (e.g., signal paths exist along a communicative chain).

While the above descriptions and connected figures may depict optical device components as separate elements, skilled persons will appreciate the various possibilities to combine or integrate discrete optical functions into a single element. Such may include combining two or more components from a single component. Conversely, skilled persons will recognize the possibility to separate a single element into two or more discrete elements, such as splitting a single component into two or more separate component.

It is appreciated that implementations of methods detailed herein are exemplary in nature, and are thus understood as capable of being implemented in a corresponding device. Likewise, it is appreciated that implementations of devices detailed herein are understood as capable of being implemented as a corresponding method. It is thus understood that a device corresponding to a method detailed herein may include one or more components configured to perform each aspect of the related method.

All acronyms defined in the above description additionally hold in all claims included herein.

While the disclosure has been particularly shown and described with reference to specific embodiments, it should be understood by those skilled in the art that various changes in form and detail may be made therein without departing from the spirit and scope of the disclosure as defined by the appended claims. The scope of the disclosure is thus indicated by the appended claims and all changes which come within the meaning and range of equivalency O the claims are therefore intended to be embraced.

### REFERENCE NUMERAL LIST

100 optical metalens component
102-i optical nano-element (e.g. pillar)
104 substrate, dielectric layer
106 lateral extension of optical nano-element (e.g. diameter of pillar)
108 distance, pitch
110 mirror structure
112 coating layer
120 center axis of optical nano-element
180 light of light source
190 light source
202 active region
204 n-contact layer
206 p-contact layer
208 aperture structure
210 contact layer
302 transmitted laser pulses
304 reflected continuous wave
306 diagram
308 resonance
400 field evolution
402 time
404 field amplitude
406 transient regime
408 uncompensated incident wave
410 fully compensated incident wave
412 steady state regime
600, 602, 604 method and method steps

1. A pulsed laser source, comprising:
an emitting structure configured to generate a continuous wave of a coherent electromagnetic radiation of a frequency; and
at least one mirror structure comprising a plurality of optical nano-elements,
wherein the plurality of optical nano-elements is configured to comprise a resonance frequency corresponding to the frequency of the coherent electromagnetic radiation such that the continuous wave of coherent electromagnetic radiation is substantially reflected from the mirror structure.

2. The pulsed laser source of claim 1, wherein the pulsed laser source comprises an optical cavity, wherein the plurality of optical nano-elements is arranged outside of the optical cavity.

3. The pulsed laser source of claim 1, wherein the optical nano-elements of at least a subset of the plurality of optical nano-elements are arranged in arrangement positions, wherein the resonance frequency corresponds to a pitch between the optical nano-elements in the arrangement positions.

4. The pulsed laser source of claim 1, wherein the optical nano-elements of at least a subset of the plurality of optical nano-elements are arranged in a regular grid of positions.

5. The pulsed laser source of claim 1, wherein the coherent electromagnetic radiation comprises a coherence length, and wherein the mirror structure is arranged within the coherence length.

6. The pulsed laser source of claim 1, wherein the pulsed laser source is configured that substantially none of the coherent electromagnetic radiation of the continuous wave is emitted to an environment of the pulsed laser source.

7. The pulsed laser source of claim 1, wherein the mirror structure is a first mirror structure and the pulsed laser source further comprises a second mirror structure, wherein the second mirror structure comprises a distributed Bragg reflector.

8. The pulsed laser source of claim 1, wherein the mirror structure is a first mirror structure and the pulsed laser source further comprises a second mirror structure, wherein the second mirror structure comprises a plurality of optical nano-elements, wherein the plurality of optical nano-elements is configured to comprise a resonance frequency corresponding to the frequency of the coherent electromagnetic radiation such that the continuous wave of coherent electromagnetic radiation is substantially reflected from the mirror structure.

9. The pulsed laser source of claim 1, wherein the mirror structure is arranged at a light emission side of the pulsed laser source.

10. A method for manufacturing a pulsed laser source, the method comprising:
forming an emitting structure configured to generate a continuous wave of a coherent electromagnetic radiation of a frequency; and
forming at least one mirror structure comprising a plurality of optical nano-elements,
wherein the plurality of optical nano-elements is configured to comprise a resonance frequency corresponding to the frequency of the coherent electromagnetic radiation such that the continuous wave of coherent electromagnetic radiation is substantially reflected from the mirror structure.

11. The method of claim 10, wherein the coherent electromagnetic radiation comprises a coherence length, and wherein the mirror structure is arranged within the coherence length.
